(19) United States
(12) Patent Application Publication
(10) Pub. No.: US 2010/0301365 A1
(43) Pub. Date: Dec. 2, 2010

(54) LIGHT EMITTING DIODE MODULE AND MANUFACTURE METHOD THEREOF

(75) Inventors: BILL CHUANG, YILAN COUNTY (TW); CHI Chih LIN, TAOYUAN COUNTY (TW)

Correspondence Address: ROSENBERG, KLEIN & LEE, 3458 ELLICOTT CENTER DRIVE-SUITE 101, ELLICOTT CITY, MD, 21043, US

(73) Assignee: TAIWAN SOLUTIONS SYSTEMS CORP., Hsinchu City (TW)

(21) Appl. No.: 12/784,729

(22) Filed: May 21, 2010

(30) Foreign Application Priority Data
May 27, 2009 (CN) 200910203471.1

(51) Int. Cl. H01L 33/60; H01L 21/50

(52) U.S. Cl. 257/98; 438/27; 257/E33.067; 257/E21.499

(57) ABSTRACT

A manufacture method of light emitting diode (LED) module includes: providing a carrier board including a carrying area and a shaping area; arranging at least one substrate having at least one circuit layer in the carrying area of the carrier board; arranging at least one LED in the carrying area of the carrier board; electrically connecting the LED to the circuit layer of the substrate; encapsulating the LED and at least part of the circuit layer by at least one light transmissive encapsulation element; and fabricating the shaping area of the carrier board into a desired appearance. The above-mentioned carrier board not only can be a heat sink but also can be easily fabricated into various types of design shapes. Therefore, a light emitting diode module manufactured by the above-mentioned method has preferred heat dissipation effects and a better appearance with relatively low production costs.

### BACKGROUND OF THE INVENTION

1. Field of the Invention

The present invention relates to a LED module and a manufacture method thereof, particularly to a LED module that can be easily processed into various shapes and a manufacture method thereof.

2. Description of the Related Art

LED (Light Emitting Diode) has advantages of compactness, long lifetime and high energy efficiency. Therefore, LED is extensively applied to illuminators, traffic lights and decorative lights. However, heat dissipation is always a challenge for LED, particularly for high-power LED.

In the conventional LED module, LED is encapsulated beforehand, and then the encapsulated LED is installed on a heat sink. With the increasing power consumption of LED, the volume of the heat sink is also increased to enhance the heat-dissipation effect. However, the existing fabrication platforms are unsuitable to fabricate a LED module containing a heat sink having a bulky volume or fins. Therefore, the manufacturers have to purchase additional fabrication platforms meeting the requirements. Thus is increased the fabrication cost. Besides, heat sinks normally have fixed shapes. Thus, heat sinks usually limit the flexibility of design, especially the heat sinks having a bulky volume or fins.

Therefore, many manufacturers are eager to develop a LED module, which not only dissipates heat effectively but also provides flexibility for appearance design.

### SUMMARY OF THE INVENTION

The present invention is directed to a LED module and a manufacture method thereof, wherein LED is arranged in a relatively thinner carrier board and encapsulated there and the carrier board is then machined to have a desired shape, wherefore the appearance of the LED module can be arbitrarily designed. In one embodiment, the carrier board including high thermal conductivity material can be a heat sink to effectively dissipate heat.

In one embodiment, the proposed LED module comprises a carrier board, at least one substrate, at least one LED, and at least one light-transmissive encapsulation element. The carrier board has a carrying area and a shaping area. The shaping area is used to form a desired shape. The substrate is arranged in the carrying area and has at least one circuit layer. The LED is also arranged in the carrying area and electrically connected with the circuit layer of the substrate. The light-transmissive encapsulation element is used to encapsulate the LED and at least one part of the circuit layer.

In another embodiment, the proposed manufacture method of a LED module comprises: providing a carrier board having a carrying area and a shaping area; arranging at least one substrate in the carrying area of the carrier board, wherein the substrate has at least one circuit layer; arranging at least one LED in the carrying area of the carrier board; electrically connecting the LED with the circuit layer; encapsulating the LED and at least one part of the circuit layer with at least one light-transmissive encapsulation element; and fabricating the shaping area of the carrier board into a desired appearance.

Below, the embodiments are described in detail in cooperation with the attached drawings to make easily understood the objectives, technical contents, characteristics and accomplishments of the present invention.

### BRIEF DESCRIPTION OF THE DRAWINGS

FIG. 1a is a sectional view of a LED module according to a first embodiment of the present invention;

FIG. 1b is a top view of a LED module, whose light-transmissive encapsulation element is removed, according to the first embodiment of the present invention;

FIG. 2a is a sectional view of a LED module according to a second embodiment of the present invention;

FIG. 2b is a top view of a LED module, whose light-transmissive encapsulation element is removed, according to the second embodiment of the present invention;

FIG. 3a is a sectional view of a LED module according to a third embodiment of the present invention;

FIG. 3b is a top view of a LED module, whose light-transmissive encapsulation element is removed, according to the third embodiment of the present invention;

FIG. 4 and FIG. 5 are sectional views of the appearances of different LED modules respectively according to different embodiments of the present invention;

FIG. 6 is a sectional view of a LED module according to a fourth embodiment of the present invention;

FIG. 7 is a sectional view of a LED module according to a fifth embodiment of the present invention;

FIG. 8 shows a flowchart of a manufacture method of a LED module according to one embodiment of the present invention; and

FIG. 9 is a top view of a carrier board of a LED module according to a sixth embodiment of the present invention.

### DETAILED DESCRIPTION OF THE INVENTION

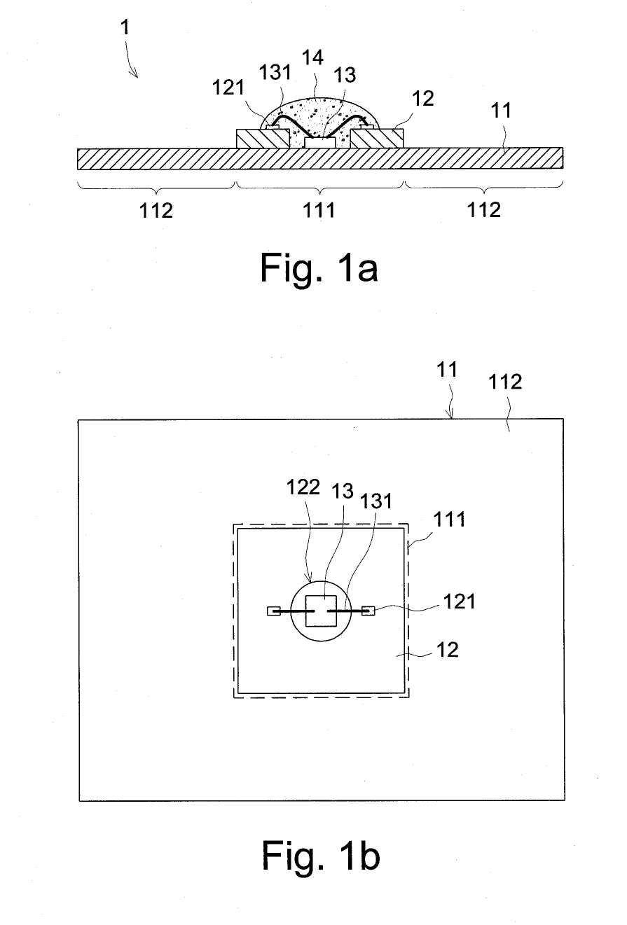

Refer to FIG. 1a and FIG. 1b. FIG. 1a is a sectional view of a LED module according to one embodiment of the present invention. FIG. 1b is a top view of a LED module, whose light-transmissive encapsulation element is removed, according to one embodiment of the present invention. In one embodiment, the LED module 1 of the present invention comprises a carrier board 11, at least one substrate 12, at least one LED 13 and at least one light-transmissive encapsulation element 14. The carrier board 11 has a carrying area 111 and a shaping area 112. The shaping area 112 can be arbitrarily machined to achieve the designed appearance. The substrate 12 is arranged in the carrying area 111 of the carrier board 11 and has at least one circuit layer. In one embodiment, the circuit layer has at least one conductive contact point 121. The substrate 12 may be but is not limit to a copper foil substrate, an insulating substrate, a glass fiber reinforced substrate, a ceramic substrate, a composite substrate, a flexible substrate, a glass fiber reinforced prepreg, or a polymeric substrate. The present invention does not limit the number of the circuit layers. In one embodiment, the several substrates are stacked vertically.

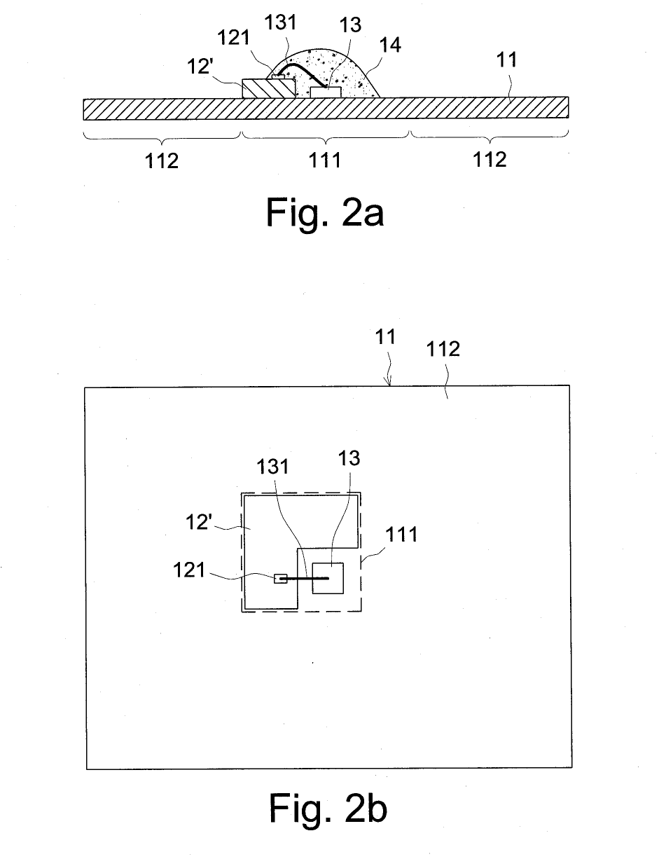

The LED 13 is also arranged in the carrying area 111 of the carrier board 11. In one embodiment, the substrate 12 has a hole 122, as shown in FIG. 1b. The LED 12 is arranged in the hole 122 and thus secured in the carrying area 111 of the carrier board 11. Each hole 122 can receive one or more LEDs 13. In other words, the side wall of the hole 122 encircles one or more LEDs 13. Refer to FIG. 2a and FIG. 2b. The LED 13 is arranged in the carrying area 111 of the carrier board 11 and beside the substrate 12′.

Refer to FIG. 1a and FIG. 1b again. The LED 13 is electrically connected with the circuit layer of the substrate 12. In one embodiment, the LED 13 is electrically connected with the conductive contact points 121 of the substrate 12 via at least one wire 131. The light-transmissive encapsulation element 14 is used to encapsulate the LED 13 and at least one part of the circuit layer, such as the conductive contact points 121. In one embodiment, the light-transmissive encapsulation element 14 is made of a polymeric material. In one embodiment, the LED module of the present invention may further comprise a fluorescent material. The fluorescent material is arranged on the surface of the LED 13, or mixed with a polymeric material, or in form of a fluorescent film arranged over the LED 13.

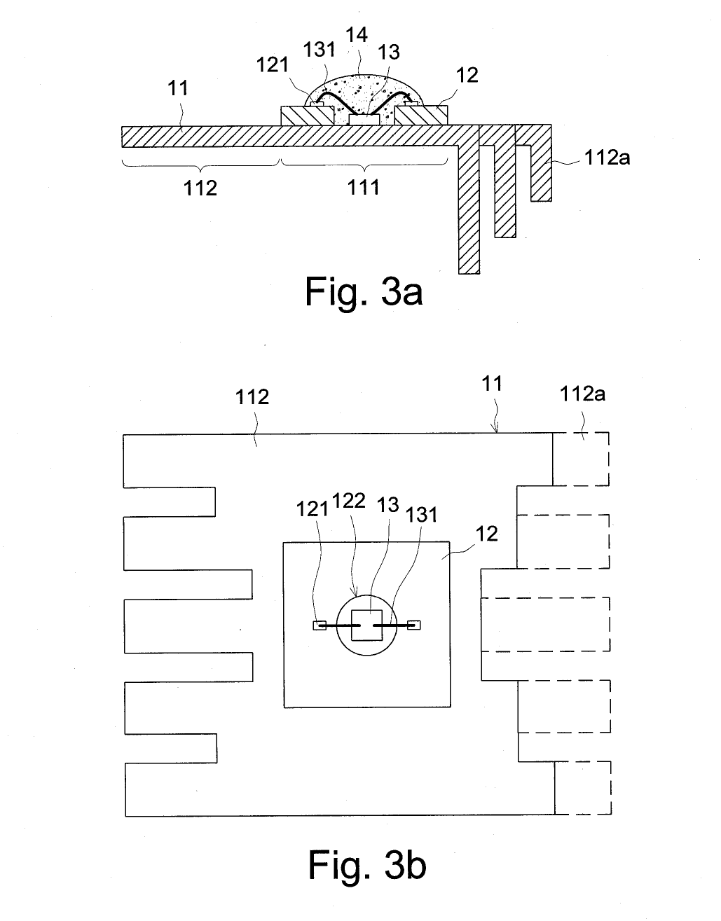

In one embodiment, the carrier board 11 may be a high thermal conductivity material, such as a metallic material, or a composite material. In such a case, the carrier board 11 can function as a heat sink. The size of the carrier board 11 is far greater than that of the substrate 12 so as to increase heat dissipation effect and benefit appearance design. Refer to FIG. 3a and FIG. 3b. In one embodiment, the shaping area 112 of the carrier board 11 is bent far away from the substrate 12 to function as a heat dissipating fin 112a. In one embodiment, the shaping area 112 of the carrier board 11 is bent toward the substrate 12 to function as a reflecting structure 112b and/or a heat dissipating structure.

Refer to FIG. 5. In one embodiment, the carrier board 11 may be a multi-layer structure. One layer of the shaping area 112 of the carrier board 11 is bent far away from the substrate 12 to function as a heat-dissipating fin 112a. Another layer of the shaping area 112 is bent toward the substrate 12 to function as a reflecting structure 112b and/or a heat dissipating structure. In one embodiment, the substrate-facing surface of the reflecting structure 112b is treated with an anodic process to enhance the reflecting effect. In one embodiment, a reflecting layer is coated on the substrate-facing surface of the reflecting structure 112b to enhance the reflecting effect.

In one embodiment, the carrier board 11 also includes an electrically-conductive material, whereby the carrier board 11 is electrically connected with the LED 13 and the circuit layer of the substrate 12. Thus, the LED 12 and the circuit layer are electrically connected with the external circuits via the carrier board 11. In one embodiment, the carrier board 11 functions as the electric-conduction element between the LED 13 and the circuit layer of the substrate 12. For example, the LED 13 is electrically with the carrier board 11 via at least one conductive bump, and the carrier board 11 is electrically connected with the circuit layer of the substrate 12, whereby the LED 12 is electrically connected with the circuit layer of the substrate 12 via the carrier board 11.

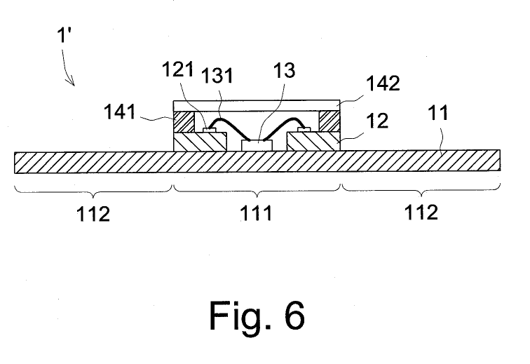

Refer to FIG. 6. In one embodiment, the light-transmissive encapsulation element 14 of the LED module 1′ further comprises a spacer 141 and a light-transmissive plate 142. The spacer 141 is arranged on the substrate 12, and the light-transmissive plate 142 is arranged over the spacer 141, whereby a gap exists between the LED 13 and the light-transmissive plate 142. Thus, the light-transmissive plate 142 is less affected by the heat generated by the LED 13. Then, the fluorescent material, which is stuck to or coated on the inner or outer surface of the light-transmissive plate 142 or mixed within the light-transmissive plate 142, is less likely to be deteriorated by the heat generated by the LED 13.

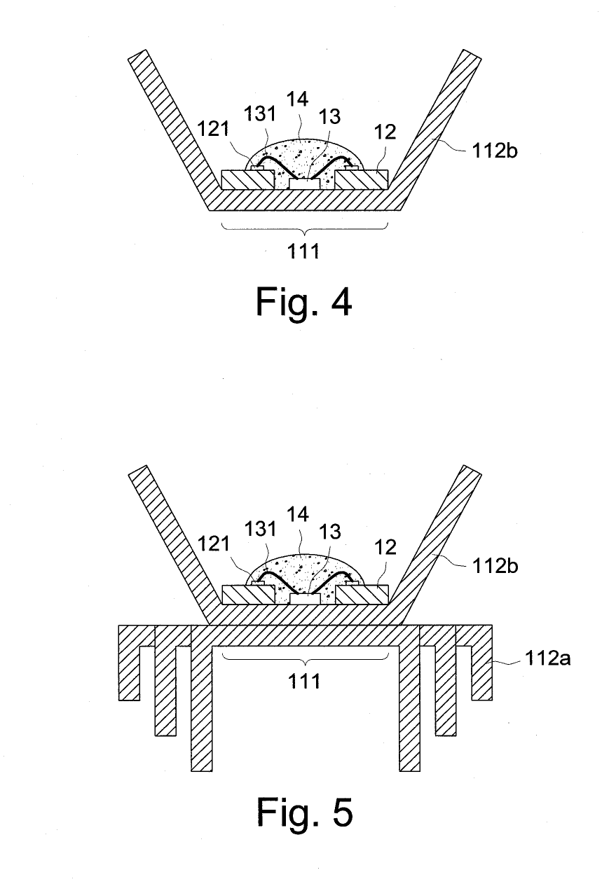

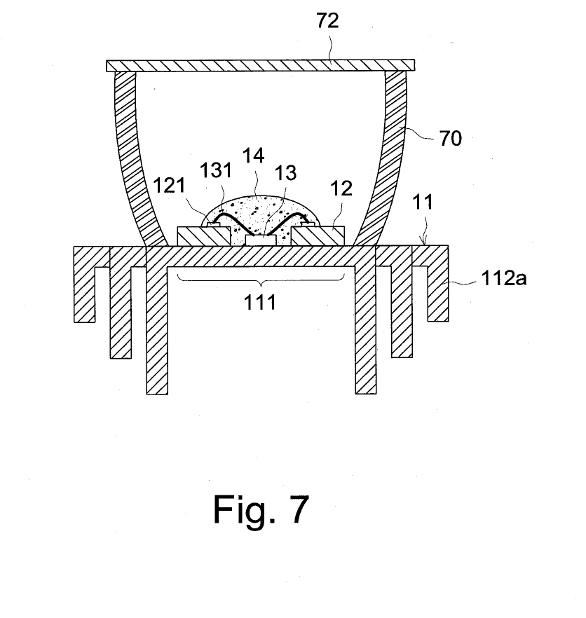

Refer to FIG. 7. In one embodiment, the LED module of the present invention further comprises a reflecting cup 70 arranged on one surface (of the carrier board 11) where the LED 13 is installed. The reflecting cup 70 may be a high thermal conductivity material, a metallic material, a composite material. Therefore, the heat generated by the LED 13 can be conducted to the reflecting cup 70 by the carrier board 11 and then dissipated by the reflecting cup 70. In one embodiment, the LED module of the present invention further comprises a diffusion element 72, such as a diffusion film. The diffusion element 72 is arranged on the light exiting side of the LED 13, such as the opening of the reflecting cup 70 or reflecting structure 112b (shown in FIG. 4). The diffusion element 72 can homogenize or milden the light emitted by the LED 13.

In one embodiment, the LED module of the present invention further comprises a driver adaptor (not shown in the drawings). The driver adaptor is electrically connected with the LED 13 and used to drive the LED 13. The driver adaptor has a connector able to electrically connect with a conventional lamp socket. Thus, the LED module of the present invention can electrically connect with any arbitrary conventional lamp socket through the driver adaptor and obtain power from the lamp socket. In one embodiment, the driver adaptor is electrically connected with the LED 13 in a plug-in way. When the LED 13 is damaged, the user needn't replace the whole lamp assembly but just replaces the damaged LED 13. In one embodiment, the driver adaptor is electrically connected with the LED 13 by at least one wire, whereby the LED module of the present invention is compatible with the conventional lamp socket, which is parallel or vertical to the light exiting direction.

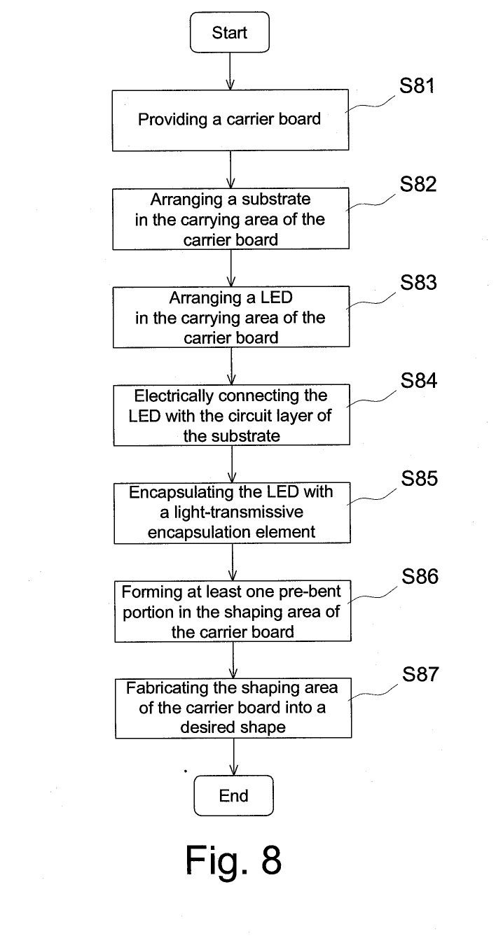

Refer to FIG. 8 and FIG. 1a. Below is described a manufacture method of a LED module according to the present invention. In Step S81, provide a carrier board 11 firstly, wherein the carrier board 11 has a carrying area 111 and a shaping area 112. In Step S82, arrange a substrate 12 having a circuit layer in the carrying area 111 of the carrier board 11. In Step S83, arrange a LED 13 in the carrying area 111 of the carrier board 11. In Step S84, electrically connect the LED 13 with the circuit layer of the substrate 12. In Step S85, encapsulate the LED 13 and at least one part of the circuit layer of the substrate 12 with a light-transmissive encapsulation element 14, such as conductive contact points 121. In Step S85, fabricate the shaping area 112 of the carrier board 11 into a desired appearance, such as a heat dissipating fin 112a shown in FIG. 3a, or a reflecting structure 112b and/or a heat dissipating structure shown in FIG. 4.

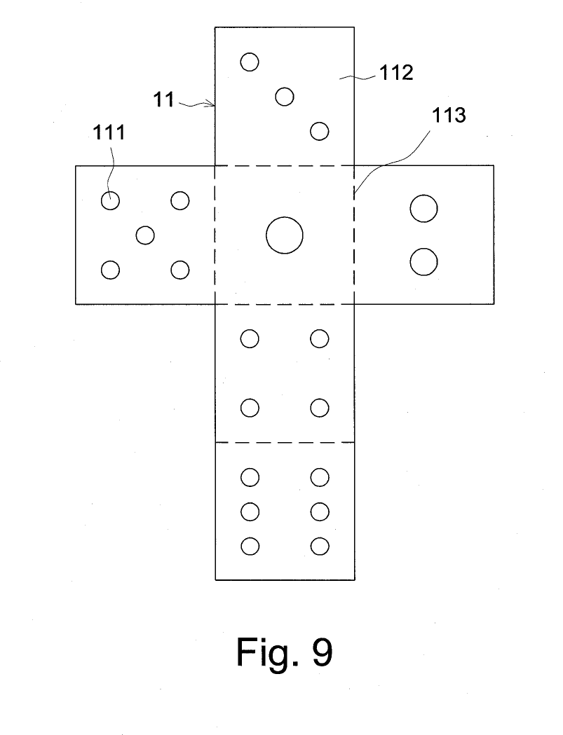

Refer to FIG. 9. In one embodiment, the method of the present invention further comprises a step of forming at least one pre-bent portion 113 in the shaping area 112 of the carrier board 11 (Step S86). Later, the user can form the predetermined appearance via merely bending shaping area 112 along the pre-bent portions 113. For example, the substrate and LED are installed in the carrying area 111 beforehand, and then the carrier board 11 is bent along the pre-bent portions 113 to form a dice-shape LED module. The dice-shape semi-product of a LED module with relatively flatter shape is favorable for storage and transportation. Thus, the related cost is reduced.

In one embodiment, the LED module is applied to a backlight module of an LCD device. In one embodiment, the two sides of the shaping area 111 are bent toward the LED 13 to form a U-shape side-emitting backlight module. Besides, the LED module of the present invention is also applied to the bottom-emitting backlight modules.

In conclusion, the present invention proposes a LED module and a manufacture method thereof, wherein the LED is arranged in a relatively thinner carrier board and encapsulated there and the carrier board is then machined to have a desired shape. Therefore, the LED module of the present invention can be fabricated without using any special specification platform. Further, the carrier board is favorable for the succeeding fabrication and can be fabricated into various shapes. In one embodiment, the carrier board is made of a high thermal conductivity material and functions as a heat sink able to dissipate heat appropriately. In other words, the heat-dissipating component can be fabricated into different shapes to implement the LED modules of various appearances in the present invention.

What is claimed is:

1. A light emitting diode module comprising:
a carrier board having a carrying area and a shaping area able to be fabricated into a desired shape;
at least one substrate arranged in the carrying area of the carrier board, having at least one circuit layer, and having a size smaller than the carrier board;
at least one light emitting diode (LED) arranged in the carrying area of the carrier board and electrically connected with the circuit layer of the substrate; and
at least one light-transmissive encapsulation element encapsulating the light emitting diode and at least one part of the circuit.

2. The light emitting diode module according to claim 1, wherein the carrier board comprises a high thermal conductivity material, a metallic material, or a composite material.

3. The light emitting diode module according to claim 2, wherein the shaping area of the carrier board is bent far away from the substrate to function as a heat-dissipating fin or bent toward the substrate to function as a reflecting structure and/or a heating-dissipating structure.

4. The light emitting diode module according to claim 2, wherein the carrier board is a multi-layer structure, and wherein one layer of the shaping area is bent far away from the substrate to function as a heat-dissipating fin, and wherein another layer of the shaping area is bent toward the substrate to function as a reflecting structure.

5. The light emitting diode module according to claim 3, wherein a LED-facing surface of the shaping area of the carrier board is treated with an anodic process or coated with a reflecting layer.

6. The light emitting diode module according to claim 1, wherein the substrate has a hole, and wherein a side wall of the hole encircles one or more the light emitting diodes.

7. The light emitting diode module according to claim 1, wherein the light emitting diode is electrically connected with the circuit layer of the substrate via at least one wire or conductive bump.

8. The light emitting diode module according to claim 1, wherein the light-transmissive encapsulation element comprises a polymeric material, or comprises a spacer and a light-transmissive plate, and wherein the spacer is arranged on the substrate, and the light-transmissive plate is arranged over the spacer, and wherein a gap exists between the light emitting diode and the light-transmissive plate.

9. The light emitting diode module according to claim 8 further comprising a fluorescent material, wherein the fluorescent material is arranged on a surface of the light-transmissive plate or the light emitting diode, or mixed with the polymeric material or the light-transmissive plate, or in form of a fluorescent film arranged over the light emitting diode.

10. The light emitting diode module according to claim 1 applying to a side-emitting backlight module or a bottom-emitting backlight module.

11. The light emitting diode module according to claim 1 further comprising a reflecting cup arranged at the light emitting diode side of the carrier board, wherein the reflecting cup includes a high thermal conductivity material, a metallic material, or a composite material.

12. The light emitting diode module according to claim 1 further comprising a diffusion element arranged on a light exiting side of the light emitting diode.

13. The light emitting diode module according to claim 1 further comprising a driver adaptor, wherein the driver adaptor is electrically connected with the light emitting diode to drive the light emitting diode and has a connector able to electrically connect with a lamp socket.

14. The light emitting diode module according to claim 13, wherein the driver adaptor is electrically connected with the light emitting diode in a plug-in way or via a wire.

15. A manufacture method of a light emitting diode module comprising:
providing a carrier board having a carrying area and a shaping area;
arranging at least one substrate in the carrying area of the carrier board, wherein the substrate has at least one circuit layer and has a size smaller than the carrier board;
arranging at least one light emitting diode in the carrying area of the carrier board;
electrically connecting the light emitting diode with the circuit layer of the substrate;
encapsulating the light emitting diode and at least one part of the circuit layer of the substrate with at least one light-transmissive encapsulation element; and
fabricating the shaping area of the carrier board into a desired appearance.

16. The manufacture method of a light emitting diode module according to claim 15 further comprising: forming at least one pre-bent portion in the shaping area of the carrier board.

17. The manufacture method of a light emitting diode module according to claim 15, wherein the carrier board comprises a high thermal conductivity material, a metallic material, or a composite material.

18. The manufacture method of a light emitting diode module according to claim 17, wherein the shaping area of the carrier board is bent far away from the substrate to function as a heat-dissipating fin or bent toward the substrate to function as a reflecting structure and/or a heating-dissipating structure.

19. The manufacture method of a light emitting diode module according to claim 17, wherein the carrier board is a multi-layer structure, and wherein one layer of the shaping area is bent far away from the substrate to function as a heat-dissipating fin, and wherein another layer of the shaping area is bent toward the substrate to function as a reflecting structure.

20. The manufacture method of a light emitting diode module according to claim 15, wherein the substrate has a hole, and wherein a side wall of the hole encircles one or more the light emitting diodes.

21. The manufacture method of a light emitting diode module according to claim 15, wherein the light emitting diode is electrically connected with the circuit layer of the substrate via at least one wire or conductive bump.

22. The manufacture method of a light emitting diode module according to claim 15, wherein the light-transmissive encapsulation element comprises a polymeric material, or comprises a spacer and a light-transmissive plate, and wherein the spacer is arranged on the substrate, and the light-transmissive plate is arranged over the spacer, and wherein a gap exists between the light emitting diode and the light-transmissive plate.

23. The manufacture method of a light emitting diode module according to claim 22, wherein a fluorescent material is arranged on a surface of the light-transmissive plate or the light emitting diode, or mixed with the polymeric material or the light-transmissive plate, or in form of a fluorescent film arranged over the light emitting diode.
